(19) United States
(12) Patent Application Publication
(10) Pub. No.: US 2026/0075960 A1
(43) Pub. Date: Mar. 12, 2026

(54) SEMICONDUCTOR DEVICE, SEMICONDUCTOR MODULE, AND ELECTRONIC APPARATUS

(71) Applicant: SONY SEMICONDUCTOR SOLUTIONS CORPORATION, KANAGAWA (JP)

(72) Inventor: KATSUHIKO TAKEUCHI, KANAGAWA (JP)

(21) Appl. No.: 19/101,772

(22) PCT Filed: Jun. 28, 2023
(86) PCT No.: PCT/JP2023/023897

§ 371 Date: Feb. 6, 2025

(30) Foreign Application Priority Data
Aug. 16, 2022 (JP) 2022-129573

(51) Int. Cl. H10D 89/60; H02H 9/00; H02H 9/04; H10D 30/47

(52) U.S. Cl. CPC H10D 89/811; H02H 9/005; H02H 9/04; H10D 30/471

(57) ABSTRACT

A semiconductor device includes a multi-gate transistor, a first terminal, and a second terminal. The multi-gate transistor includes field effect transistors that each have a pair of main electrodes and a gate electrode disposed between the pair of main electrodes and that are electrically coupled in series while sharing the main electrodes. The first terminal is electrically coupled to one of the main electrodes of the field effect transistor at one end of the series-coupled field effect transistors of the multi-gate transistor, and receives or outputs a signal. The second terminal is electrically coupled to another of the main electrodes of the field effect transistor at another end of the series-coupled field effect transistors of the multi-gate transistor and receives supply of a fixed potential. The gate electrode of at least one of the field effect transistors of the multi-gate transistor is electrically coupled to the other main electrode of the same field effect transistor.

### TECHNICAL FIELD

The present disclosure relates to a semiconductor device, a semiconductor module, and an electronic apparatus.

### BACKGROUND ART

GaN is used as a wide gap semiconductor material. A device formed by GaN is characterized by, for example, a high dielectric breakdown voltage, the capability of performing high temperature operation, and a fast saturation drift speed. Moreover, it is also characterized by high mobility and high sheet electron density in two-dimensional electronic gas (2DEG) generated in GaN-based hetero bonding.

With these characteristics, a GaN-based hetero field effect transistor (HFET) has the capability of low resistance, high speed operation, and high voltage operation. Thus, application to a power device, a high frequency device (RF), and so on is expected.

A high frequency device using a compound semiconductor such as GaN typically has excellent high frequency characteristics but is weak against electrostatic discharge (ESD) breakdown. Thus, countermeasures against electrostatic discharge breakdown are desired.

Patent Literature 1 below discloses an electrostatic protection circuit. The electrostatic protection circuit includes a plurality of metal oxide semiconductor (MOST) transistors that is disposed between an external terminal and a power terminal and that are electrically coupled in series with one drain and another source coupled. Respective gate electrodes of the plurality of MOS transistors are coupled to source electrodes. Moreover, the plurality of MOS transistors is electrically isolated from each other through element isolation.

With the electrostatic protection circuit configured as described above, static electricity applied to an external terminal is voltage-divided into the plurality of MOS transistors. Thus, it is possible to improve an electrostatic discharge breakdown voltage

### CITATION LIST

### Patent Literature

Patent Literature 1: Japanese Unexamined Patent Application Publication No. 2001-339044

### SUMMARY OF THE INVENTION

In the electrostatic protection circuit described above, a plurality of MOS transistors is separated by device isolation; therefore, an increase in the number of connections of the MOS transistors increases an occupied area. Thus, it has been desired to improve an electrostatic breakdown voltage and reduce an occupied area in an electrostatic breakdown protection circuit disposed at an external terminal to which a DC signal is applied in a semiconductor device which forms a power transistor, a high frequency device, and so on.

A semiconductor device according to a first mode of the present disclosure includes a multi-gate transistor, a first terminal, and a second terminal. The multi-gate transistor includes a plurality of field effect transistors each having a pair of main electrodes and a gate electrode disposed between the pair of main electrodes. The field effect transistors are electrically coupled in series while sharing the main electrodes. The first terminal is electrically coupled to one of the main electrodes of the field effect transistor at one end of the series-coupled field effect transistors of the multi-gate transistor. The first terminal receives or outputs a signal. The second terminal is electrically coupled to another of the main electrodes of the field effect transistor at another end of the series-coupled field effect transistors of the multi-gate transistor. The second terminal receives supply of a fixed potential. The gate electrode of at least one of the field effect transistors of the multi-gate transistor is electrically coupled to the other main electrode of the same field effect transistor.

Here, the multi-gate transistor is included in an electrostatic breakdown protection circuit.

A semiconductor module according to a second mode of the present disclosure includes a semiconductor device. The semiconductor device includes a multi-gate transistor, a first terminal, and a second terminal. The multi-gate transistor includes a plurality of field effect transistors each having a pair of main electrodes and a gate electrode disposed between the pair of main electrodes. The field effect transistors are electrically coupled in series while sharing the main electrodes. The first terminal is electrically coupled to one of the main electrodes of the field effect transistor at one end of the series-coupled field effect transistors of the multi-gate transistor. The first terminal receives or outputs a signal. The second terminal is electrically coupled to another of the main electrodes of the field effect transistor at another end of the series-coupled field effect transistors of the multi-gate transistor. The second terminal receives supply of a fixed potential. The gate electrode of at least one of the field effect transistors of the multi-gate transistor is electrically coupled to the other main electrode of the same field effect transistor.

An electronic apparatus according to a third mode of the present disclosure includes a semiconductor device. The semiconductor device includes a multi-gate transistor, a first terminal, and a second terminal. The multi-gate transistor includes a plurality of field effect transistors each having a pair of main electrodes and a gate electrode disposed between the pair of main electrodes. The field effect transistors are electrically coupled in series while sharing the main electrodes. The first terminal is electrically coupled to one of the main electrodes of the field effect transistor at one end of the series-coupled field effect transistors of the multi-gate transistor. The first terminal receives or outputs a signal. The second terminal is electrically coupled to another of the main electrodes of the field effect transistor at another end of the series-coupled field effect transistors of the multi-gate transistor. The second terminal receives supply of a fixed potential. The gate electrode of at least one of the field effect transistors of the multi-gate transistor is electrically coupled to the other main electrode of the same field effect transistor.

### BRIEF DESCRIPTION OF THE DRAWINGS

FIG. 1 is a circuit diagram including an electrostatic discharge protection circuit (ESD protection device) and an internal circuit loaded in a semiconductor device according to a first embodiment of the present disclosure.

FIG. 2 is a plan view of the electrostatic discharge protection circuit illustrated in FIG. 1.

FIG. 3 is a cross-sectional view of main parts of the electrostatic discharge protection circuit illustrated in FIG. 2 (a cross-sectional view taken along a cut line A-A illustrated in FIG. 2).

FIG. 4 is a cross-sectional view of main parts of the electrostatic discharge protection circuit illustrated in FIG. 2 (a cross-sectional view taken along a cut line B-B illustrated in FIG. 2)

FIG. 5 is a cross-sectional view of a first process illustrating, on an individual process basis, a method for manufacturing the semiconductor device loaded with the electrostatic discharge protection circuit illustrated in FIGS. 1 to 3 (a cross-sectional view corresponding to a cross section taken along the cut line A-A illustrated in FIG. 2).

FIG. 6 is a cross-sectional view of a second process.

FIG. 7 is a cross-sectional view of a third process.

FIG. 8 is a cross-sectional view of a fourth process.

FIG. 9 is a cross-sectional view of a fifth process.

FIG. 10 is a cross-sectional view of a sixth process.

FIG. 11 is a schematic plan view of the electrostatic discharge protection circuit according to the first embodiment.

FIG. 12 is a schematic plan view of an electrostatic discharge protection circuit according to Comparative Example 1.

FIG. 13 is a graph comparing an occupied area of the electrostatic discharge protection circuit according to the first embodiment and an occupied area of the electrostatic discharge protection circuit according to Comparative Example 1.

FIG. 14 is a plan view corresponding to FIG. 2, illustrating an electrostatic discharge protection circuit loaded in a semiconductor device according to a second embodiment of the present disclosure.

FIG. 15 is a schematic plan view corresponding to FIG. 11, illustrating the electrostatic discharge protection circuit according to the second embodiment.

FIG. 16 is a schematic plan view corresponding to FIG. 12, illustrating an electrostatic discharge protection circuit according to Comparative Example 2.

FIG. 17 is a graph comparing an occupied area of the electrostatic discharge protection circuit according to the second embodiment and an occupied area of the electrostatic discharge protection circuit according to Comparative Example 2.

FIG. 18 is a cross-sectional view of main parts of a semiconductor device and an internal circuit loaded in a semiconductor device according to a third embodiment of the present disclosure.

FIG. 19 is a cross-sectional view of main parts of a semiconductor device and an internal circuit loaded in a semiconductor device according to a fourth embodiment of the present disclosure.

FIG. 20 is a perspective view of a semiconductor module according to a fifth embodiment of the present disclosure.

FIG. 21 is a block diagram of an electronic apparatus according to a sixth embodiment of the present disclosure.

### MODES FOR CARRYING OUT THE INVENTION

Hereinafter, embodiments of the present disclosure will be described in detail with reference to the drawings. Note that the description will be given in the following order.
1. First Embodiment

The first embodiment is a first example in which the present technology is applied to a semiconductor device loaded with an electrostatic discharge protection circuit. Here, a circuit configuration, plane configuration, sectional configuration, and a manufacturing method of the electrostatic discharge protection circuit will be described.
2. Second Embodiment

The second embodiment is a second example realized by increasing the number of connections of field effect transistors in the electrostatic discharge protection circuit of the semiconductor device according to the first embodiment.
3. Third Embodiment

The third embodiment is a first example illustrating a structure of the field effect transistors monolithically formed with the electrostatic discharge protection circuit in an internal circuit of the semiconductor device according to the first embodiment or the second embodiment.
4. Fourth Embodiment

The fourth embodiment is a second example illustrating a structure of the field effect transistors monolithically formed with the electrostatic discharge protection circuit in the internal circuit of the semiconductor device according to the first embodiment or the second embodiment.
5. Fifth Embodiment

The fifth embodiment is a fifth example illustrating a semiconductor module mounted with the semiconductor devices according to the first to fourth embodiments.
6. Sixth Embodiment

The sixth embodiment is a sixth example illustrating an electronic apparatus mounted with the semiconductor devices according to the first to fourth embodiments.
7. Other Embodiments

### 1. First Embodiment

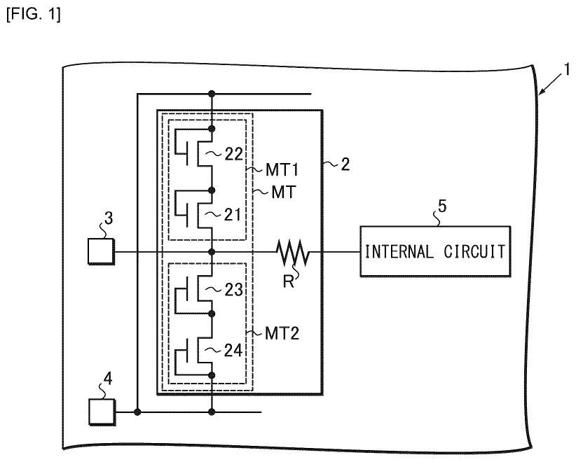

A semiconductor device 1 according to the first embodiment of the present disclosure will be described with reference to FIGS. 1 to 13.

Here, a direction of arrow X appropriately illustrated in the drawings represents one plane direction of the semiconductor device 1 loaded on a plane for convenience. A direction of arrow Y represents another plane direction orthogonal to the direction of arrow X. Moreover, a direction of arrow Z represents an upward direction orthogonal to the direction of arrow X and the direction of arrow Y. That is, the direction of arrow X, the direction of arrow Y, and the direction of arrow Z respectively just agree with an X-axis direction, a Y-axis direction, and a Z-axis direction of a three-dimensional coordinate system.

Note that each of the aforementioned directions is illustrated for helping the understanding of the description, and does not limit the directions of the present technology.

### Circuit Configuration of Semiconductor Device 1 and Electrostatic Discharge Protection Circuit 2

### (1) Overall Configuration of Semiconductor Device 1

FIG. 1 illustrates one example of a circuit configuration including the electrostatic discharge protection circuit (ESD protection device) 2 and an internal circuit 5 loaded in the semiconductor device 1 according to the first embodiment.

As illustrated in FIG. 1, the semiconductor device 1 includes: a first terminal 3, a second terminal 4, and the internal circuit 5 and further includes the electrostatic discharge protection circuit 2.

The first terminal 3 is an external signal terminal that receives a signal from an outside of the semiconductor device 1. The first terminal 3 is electrically coupled to the internal circuit 5 of the semiconductor device 1. For example, the signal is a DC signal which is greater than or equal to 2V and smaller than or equal to 20V or greater than or equal to −20 V and smaller than or equal to −2V.

The second terminal 4 is an external power supply terminal where power supply from the outside of the semiconductor device 1 is performed. The second terminal 4 is electrically coupled to, for example, the internal circuit 5 of the semiconductor device 1. The power is a fixed potential, for example, a circuit ground voltage of 0V.

The internal circuit 5 includes a field effect transistor that forms, for example, a power device, a high frequency device, or the like in the first embodiment. Examples of the field effect transistor used include: a GaN-based hetero field effect transistor (HFET) and a GaN-based hetero junction field effect transistor (HJFET).

Note that the DC signal is inputted to the first terminal 3 as described above, but a high frequency RF signal is not inputted to the first terminal 3. Thus, bad linearity of the electrostatic discharge protection circuit 2, if any, does not deteriorate high frequency circuit characteristics of the internal circuit 5.

### (2) Circuit Configuration of Electrostatic Discharge Protection Circuit 2

The electrostatic discharge protection circuit 2 is disposed between the first terminal 3 and the internal circuit 5. In other words, the electrostatic discharge protection circuit 2 is disposed between the first terminal 3 and the second terminal 4.

The electrostatic discharge protection circuit 2 includes a multi-gate transistor MT as a main component. The electrostatic discharge protection circuit 2 further includes a resistor R electrically coupled in series between the multi-gate transistor MT and the internal circuit 5.

The multi-gate transistor MT includes a first multi-gate transistor MT1 and a second multi-gate transistor MT2 in the first embodiment. The first multi-gate transistor MT1 includes two transistors including a first field effect transistor 21 and a second field effect transistor 22. The second multi-gate transistor MT2 includes two transistors including a third field effect transistor 23 and a fourth field effect transistor 24.

The first field effect transistor 21 to the fourth field effect transistor 24 of the multi-gate transistor MT each include a pair of main electrodes and a gate electrode disposed between the pair of main electrodes. Furthermore, another of the pair of main electrodes and the gate electrode are electrically coupled in each of the first field effect transistor 21 to the fourth field effect transistor 24.

One of the main electrodes of the first field effect transistor 21 disposed at one end of series-coupled field effect transistors of the first multi-gate transistor MT1 is coupled to the first terminal 3. Another main electrode of the first field effect transistor 21 is coupled to one of the main electrodes of the second field effect transistor 22 disposed at another end of the series-coupled field effect transistors of the first multi-gate transistor MT1. Then another main electrode of the second field effect transistor 22 is coupled to the second terminal 4. That is, the first field effect transistor 21 and the second field effect transistor 22 share the main electrodes and are electrically coupled in series between the first terminal 3 and the second terminal 4.

The phrase “share the main electrodes” here is used, meaning that the main electrode of one of the field effect transistors is formed in common to one of the main electrodes of another field effect transistor, and the aforementioned main electrodes are thus integrally formed without any connection through insulation isolation or wiring.

Moreover, in other words, the first field effect transistor 21 and the second field effect transistor 22 are electrically coupled in parallel between the first terminal 3 and the internal circuit 5.

One of the main electrodes of the third field effect transistor 23 disposed at one end of series-coupled field effect transistors of the second multi-gate transistor MT2 is coupled to the first terminal 3. Another main electrode of the third field effect transistor 23 is coupled to one of the main electrodes of the fourth field effect transistor 24 disposed at another end of the series-coupled field effect transistors of the second multi-gate transistor MT2. Then another main electrode of the fourth field effect transistor 24 is coupled to the second terminal 4. That is, the third field effect transistor 23 and the fourth field effect transistor 24 share the main electrodes and are electrically coupled in series between the first terminal 3 and the second terminal 4.

Similarly, in other words, the third field effect transistor 23 and the fourth field effect transistor 24 are electrically coupled in parallel between the first terminal 3 and the internal circuit 5.

### Detailed Device Configuration of Electrostatic Discharge Protection Circuit 2

### (1) Configuration of First Field Effect Transistor 21 to Fourth Field Effect Transistor 24

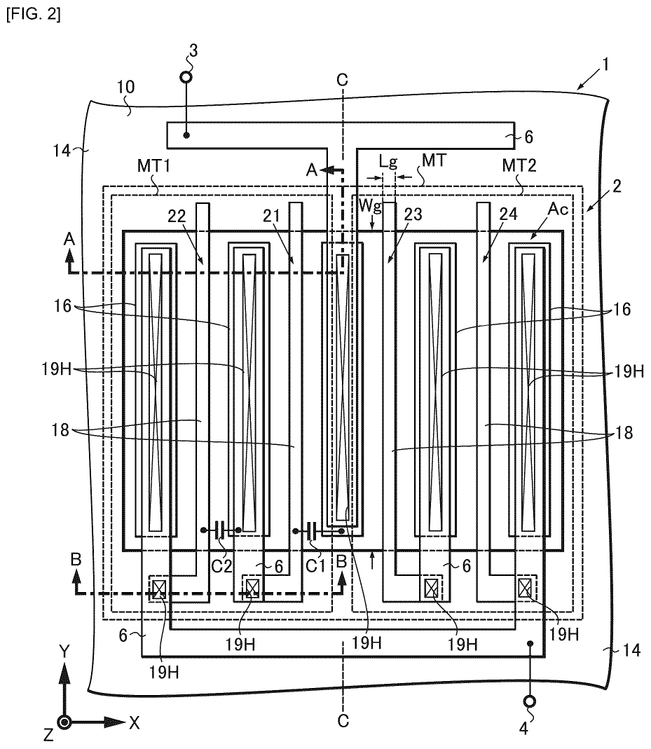

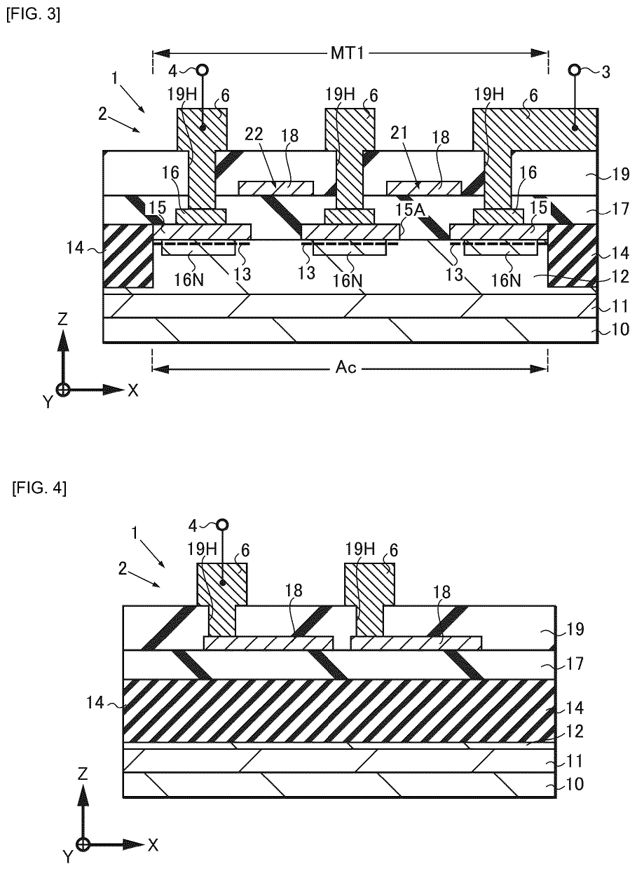

FIG. 2 illustrates one example of a plane configuration of the electrostatic discharge protection circuit 2. FIG. 3 illustrates one example of a cross-sectional configuration of the electrostatic discharge protection circuit 2. FIG. 4 illustrates one example of a cross-sectional configuration of a connection part between respective gate electrodes 18 and respective wirings 6 of the first field effect transistor 21 and the second field effect transistor 22 included in the electrostatic discharge protection circuit 2.

The semiconductor device 1 according to the first embodiment includes a substrate 10 as a main component. A buffer layer 11 is laid on a main surface of the substrate 10 in a direction of an arrow Z.

The first field effect transistor 21 to the fourth field effect transistor 24 are disposed at the substrate 10 with the buffer layer 11 interposed therebetween in an active region Ac surrounded by a device isolation region 14.

Specifically, the first field effect transistor 21 to the fourth field effect transistor 24 each include: a channel layer 12; the pair of main electrodes 16; and the gate electrode 18 disposed between the pair of main electrodes 16. One of the pair of main electrodes 16 is used as a source electrode (a source region). Here, the source electrode is electrically coupled to the first terminal 3. Another of the pair of the main electrodes 16 is used as a drain electrode (a drain region). The drain electrode is electrically coupled to the second terminal 4.

In the first field effect transistor 21, the one main electrode 16 is coupled to the first terminal 3 and the other main electrode 16 is shared and coupled as the one main electrode 16 of the second field effect transistor 22.

Furthermore, in the first field effect transistor 21, the gate electrode 18 is coupled to the other main electrode 16. The wiring 6 is used for the connection between the gate electrode 18 and the other main electrode 16. One end part of the gate electrode 18 in a gate width direction extends to the device isolation region 14, and one end part of the wiring 6 is coupled to the one end part of the gate electrode 18 extending in the aforementioned manner. On the other hand, another end part of the wiring 6 extends to a region overlapping the other main electrode 16 and is coupled to the other main electrode 16 in a region where the aforementioned other end part of the wiring 6 extends.

In the second field effect transistor 22, the other main electrode 16 is coupled to the second terminal 4 and the gate electrode 18 is coupled to the other main electrode 16. The wiring 6 is used for the connection between the gate electrode 18 and the other main electrode 16, as is the case with the first field effect transistor 21.

Similarly, in the third field effect transistor 23, the one main electrode 16 is coupled to the first terminal 3 and the other main electrode 16 is shared by and coupled to the one main electrode 16 of the fourth field effect transistor 24. Furthermore, in the third field effect transistor 23, the gate electrode 18 is coupled to the other main electrode 16. The wiring 6 is used for the connection between the gate electrode 18 and the other main electrode 16, as is the case with the first field effect transistor 21.

In the fourth field effect transistor 24, the other main electrode 16 is coupled to the second terminal 4 and the gate electrode 18 is coupled to the other main electrode 16. The wiring 6 is used for the connection between the gate electrode 18 and the other main electrode 16, as is the case with the first field effect transistor 21.

The first field effect transistor 21 to the fourth field effect transistor 24 are disposed in one active region Ac surrounded by the device isolation region 14 and configured to share the main electrodes 16. That is, the first field effect transistor 21 and the second field effect transistor 22 are included in the first multi-gate transistor MT1 and the third field effect transistor 23 and the fourth field effect transistor 24 are included in the second multi-gate transistor MT2.

A center line C-C is illustrated between the first multi-gate transistor MT1 and the second multi-gate transistor MT2 for convenience (see FIG. 2). The center line C-C extends in a direction of arrow Y at a center position, in a direction of arrow X, of the main electrodes 16 shared by the first field effect transistor 21 and the third field effect transistor 23. With the center line C-C as a center, the second multi-gate transistor MT2 is formed into a shape line symmetrical with respect to the first multi-gate transistor MT1 when viewed from a direction of arrow Z (simply referred to as in plan view).

Then the first multi-gate transistor MT1 and the second multi-gate transistor MT2 forms the multi-gate transistor MT.

### (2) Configuration of Substrate 10

A semiconductor material is used for the substrate 10. More specifically describing, for example, a III-V compound semiconductor material, for example, a nitride semiconductor here, more specifically, a semi-insulating single crystal GaN substrate is used.

Moreover, the buffer layer 11 is disposed between the substrate 10 and the channel layer 12 and a lattice constant is controlled by the buffer layer 11. Thus, it is possible to use, for the substrate 10, a semiconductor material with a different lattice constant for the channel layer 12. For example, it is possible to use, for example, Sic sapphire, Si, or the like as the semiconductor material with a difference lattice constant, for the substrate 10.

### (3) Configuration of Buffer Layer 11

The buffer layer 11 is disposed at the substrate 10. The buffer layer 11 is formed by, for example, a compound semiconductor layer grown on the substrate 10 by using an epitaxial growth method.

In a case where a lattice constant of the channel layer 12 is different from a lattice constant of the substrate 10, it is possible to control the lattice constant by the buffer layer 11. This results in a favorable crystal state of the channel layer 12, making it possible to favorably control warpage of the substrate 10 in a wafer state.

For example, in a case where the substrate 10 is formed by a single crystal Si substrate and the channel layer 12 is formed by GaN, it is possible to use, for example, AlN, AlGaN, GaN, and the like for the buffer layer 11.

Moreover, the buffer layer 11 is not limited to a single layer. For example, the buffer layer 11 may be formed by a composite film formed by appropriately laying the aforementioned AlN, AlGaN, GaN, and the like. Furthermore, the buffer layer 11 may be formed by a ternary compound semiconductor layer whose composition is gradually changed in a film thickness direction.

### (4) Configuration of Channel Layer 12

A barrier layer 15 is disposed on a side of the channel layer 12 opposite to the buffer layer 11. The channel layer 12 is a region where carries are accumulated as a result of polarization with the barrier layer 15. Near the barrier layer 15 in the channel layer 12, two-dimensional electronic gas (2DEG) 13 is generated where the carriers are accumulated and that functions as a channel region for the carries.

A compound semiconductor layer is used for the channel layer 12. For example, the channel layer 12 is formed by GaN as a nitride semiconductor. GaN is formed by using, for example, an epitaxial growth method. Here, undoped GaN (u-GaN) without any impurities added is used for the channel layer 12. Since no impurities are added, it is possible to suppress scattering by the impurities of the carriers at the channel layer 12. This consequently makes it possible to realize high carrier mobility.

Note that a back barrier layer may be disposed between the buffer layer 11 and the channel layer 12. The back barrier layer is formed by a compound semiconductor material that lifts up an energy band on a back barrier layer side in the channel layer 12. The inclusion of the back barrier layer makes it possible to effectively suppress, for example, a short channel effect in the first field effect transistor 21 to the fourth field effect transistor 24.

It is possible to practically use, as the back barrier layer, for example, Al_{1-x-y}GaₓIn_{y}N (where x is greater than or equal to 0 and smaller than 1 and y is greater than or equal to 0 and smaller tan 1), undoped Al_{1-x-y}GaₓIn_{y}N, or the like. The back barrier layer is formed by using an epitaxial growth method.

### (5) Configuration of Barrier Layer 15

The barrier layer 15 is disposed at the channel layer 12 as described above. The barrier layer 15 is formed by a compound semiconductor material with the carriers accumulated in the channel layer 12 as a result of polarization with the channel layer 12. The barrier layer 15 is formed by, for example, Al_{1-x-y}GaₓIn_{y}N (where x is greater than or equal to 0 and smaller than 1 and y is greater than or equal to 0 and smaller than 1). The barrier layer 15 is formed by using an epitaxial growth method.

The barrier layer 15 may also be formed by undoped Al_{1-x-y}GaₓIn_{y}N. Since no impurities are added, it is possible to suppress the scattering by the impurities of the carriers at the channel layer 12. This consequently makes it possible to realize high carrier mobility.

Moreover, the barrier layer 15 is not limited to a single layer. The barrier layer 15 may be formed by, for example, a composite film in which a plurality of layers obtained by changing composition of the aforementioned Al_{1-x-y}GaₓIn_{y}N (where x is greater than or equal to 0 and smaller than 1 and y is greater than or equal to 0 and smaller than 1) is laid. Furthermore, the barrier layer 15 may be formed with the composition gradually changed in the film thickness direction.

Note that a spacer layer may be disposed between the channel layer 12 and the barrier layer 15, illustration of which is omitted. It is possible for the spacer layer to effectively suppress the scattering by the impurities of the carriers, realizing high mobility.

The spacer layer is formed by a compound semiconductor material such as, for example, Al₁₋ₓGaₓN (where x is greater than or equal to 0 and smaller than 1). The spacer layer may be formed with a single layer or with a composite layer. The composite film is formed by laying a plurality of layers obtained by changing composition of the spacer layer. Moreover, the spacer layer may be formed with the composition gradually changed in the film thickness direction.

A gate barrier opening 15A is disposed in the barrier layer 15 at a middle portion between the pair of main electrodes 16 in plan view or when viewed from the direction of arrow Y (hereinafter simply referred to as “in side view”). The gate barrier opening 15A is disposed at a position overlapping the gate electrode 18 and is formed through the barrier layer 15 in the film thickness direction.

The gate barrier opening 15A is formed by selectively etching the barrier layer 15. Used for the etching is, for example, wet etching using a chemical solution with a high etching selection ratio for the channel layer 12. This makes it possible to realize selective etching of the barrier layer 15 with high accuracy.

Note that a configuration with the aforementioned spacer layer remaining in the gate barrier opening 15A makes it possible to provide a high ON current of, for example, the first field effect transistor 21.

On the contrary, a configuration with the spacer layer, in the gate barrier opening 15A, completely removed makes it possible to reduce an OFF current of, for example, the first field effect transistor 21. In case of the configuration described above, a surface layer of the channel layer 12 may be partially etched in the gate barrier opening 15A.

### (6) Configuration of Insulator 17

An insulator 17 is disposed on a side of the barrier layer 15 opposite to the channel layer 12 and at the channel layer 12 in the gate barrier opening 15A. The insulator 17 is used as a gate insulating film of, for example, the first field effect transistor 21. More specifically describing, the insulator 17 has insulation properties against the channel layer 12 and the barrier layer 15, protects the surfaces of the channel layer 12 and the barrier layer 15 from impurities such as ions, and forms a favorable interface between the channel layer 12 and the barrier layer 15. That is, the insulator 17 is formed by an insulating material that improves device characteristics of, for example, the first field effect transistor 21.

It is possible to use, as the insulator 17, at least one of insulating materials selected from, for example, aluminum oxide (Al₂O₃), hafnium oxide (HfO₂), silicon oxide (SiO₂), and silicon nitride (SiN). It is possible to form the film with each of Al₂O₃ and HfO₂ by, for example, an atomic vapor deposition (ALD) method. It is also possible to form the film with each of SiO₂ and SiN by a chemical vapor deposition (CVD) method. The insulator 17 has a film thickness set at 20 nm or more in terms of conversion into an oxide film thickness.

Note that the insulator 17 may be a single layer or a composite film where a plurality of the insulating materials selected above are laid.

### (7) Configuration of Gate Electrode 18

The gate electrode 18 is disposed on a side of the insulator 17 opposite to the channel layer 12 at a position overlapping the gate barrier opening 15A. Here, the gate electrode 18 is formed by a composite film obtained by sequentially laying nickel (Ni) and gold (Au) in a direction towards an arrow Z.

That is, for example, the first field effect transistor 21 is a gate insulated field effect transistor.

### (8) Configuration of Main Electrode 16

The main electrode 16 is disposed at the channel layer 12 with the barrier layer 15 interposed therebetween. The main electrode 16 includes an ohmic electrode for ohmic bonding (ohmic contact) to the channel layer 12. Consequently, connection between the main electrode 16 and two-dimensional electronic gas 13 provides low resistance.

The main electrode 16 is formed by, for example, a composite film obtained by sequentially laying titanium (Ti), aluminum (Al), nickel (Ni), and gold (Au) in the direction towards the arrow Z.

Furthermore, the main electrode 16 is coupled to the two-dimensional electronic gas 13 of the channel layer 12 via a high impurity density region 16N disposed between the channel layer 12 and the barrier layer 15. In plan view and side view, the high impurity density region 16N is a semiconductor region that is disposed at a position of the channel layer 12 overlapping the main electrode 16, has the same conductive type as the carriers flowing to the channel layer 12, and has higher impurity density than the channel layer 12.

In the first embodiment, electrons as carriers flow to the two-dimensional electronic gas 13, and thus the high impurity density region 16N is formed by an n-type semiconductor region. The high impurity density region 16N is formed at a position deeper towards the substrate 10 side than the two-dimensional electronic gas 13. The high impurity density region 16N is formed with an impurity density of, for example, 10¹⁸ atoms/cm3 or more and 10²¹ atoms/cm3 or less.

The inclusion of the high impurity density region 16N provides low resistance for the connection between the main electrode 16 and the two-dimensional electronic gas 13.

The high impurity density region 16N is formed by using a selective regrowth method or an ion implantation method.

The selective regrowth method is, for example, a method for partially removing the surface of the channel layer 12 through etching and selectively growing the high impurity density region 16N in a region where the aforementioned removal has been performed. In the case, it is possible to use a semiconductor material such as n-In₁₋ₓGaₓN for the high impurity density region 16N.

On the other hand, the ion implantation method is, for example, a method for implanting n-type impurities into a surface portion of the channel layer 12 and activating the implanted n-type impurities.

### (9) Configuration of Device Isolation Region 14

The device isolation region 14 is disposed at the channel layer 12 and the barrier layer 15 around the active region Ac. The device isolation region 14 is formed by using, for example, an ion implantation method. The ion implantation method is a method for implanting p-type impurities into the barrier layer 15 and the channel layer 12 and destroying crystals to reduce conductivity. For example, boron (B) is used as the p-type impurities. At the channel layer 12, the device isolation region 14 is formed from the surface of the channel layer 12 to the two-dimensional electronic gas 13 and further across a position deeper towards the substrate 10 than the high impurity density region 16N.

### (10) Configuration of Interlayer Insulator 19

The interlayer insulator 19 is disposed, covering the gate electrode 18 and the insulator 17. The interlayer insulator 19 is formed by an insulating material that has insulation properties for the gate electrode 18 and does not flow a current between the wirings 6. As is the case with the insulator 17, it is possible to use, as the interlayer insulator 19, for example, one or more insulating materials selected from Al₂O₃, HfO₂, SiO₂, and SiN. It is possible to form a film by, for example, an ALD method with each of Al₂O₃ and HfO₂. It is possible to form a film by a CVD method with each of SiO₂ and SiN.

Note that the interlayer insulator 19 may be a single layer or a composite film obtained by laying the selected plurality of insulating materials above.

### (11) Configuration of Wiring 6

The wiring 6 is disposed on a side of the interlayer insulator 19 opposite to the gate electrode 18. The wiring 6 is disposed at a position overlapping the main electrode 16 of, for example, the first field effect transistor 21 and is coupled to the main electrode 16 through a connection hole 19H formed at the insulator 17 and the interlayer insulator 19.

In the first embodiment, the main electrode 16 of, for example, the first field effect transistor 21 is formed into a slit-like shape that is short in a direction along a gate length Lg and long in a direction along a gate width Wg in plan view. Thus, the wiring 6 is disposed, overlapping most of the planar shape of the main electrode 16 and is coupled to most of the main electrode 16 through the connection hole 19H having an opening of a slit-like shape similar to the shape of the main electrode 16 in plan view.

Moreover, in the electrostatic discharge protection circuit 2 according to the first embodiment, the wiring 6 coupled to the other main electrode 16 of the first field effect transistor 21 is coupled to the gate electrode 18 of the first field effect transistor 21. The one end part of the gate electrode 18 extends to the device isolation region 14. The one end part of the gate electrode 18 is coupled to the wiring 6 through the connection hole 19H.

The second field effect transistor 22 to the fourth field effect transistor 24 have the same configuration.

The wiring 6 is formed by a wiring material having a smaller specific resistance value than respective specific resistance values of the gate electrode 18 and the main electrode 16. It is possible to use, as the wiring 6, for example, one or more wiring materials selected from Ti, Pt, Al, and Au. Here, a resistance value of the wiring 6 between the gate electrode 18 and the main electrode 16 is set at 100 Ω or below. The resistance value is more preferably set at 10 Ω or below.

### Method for Manufacturing Semiconductor Device 1 and Electrostatic Discharge Protection Circuit 2

Next, the method for manufacturing the semiconductor device 1 and the electrostatic discharge protection circuit 2 according to the first embodiment will be described. FIGS. 5 to 10 illustrate one example of a cross section of processes of a manufacturing method on an individual process basis.

First, the buffer layer 11 is formed onto the substrate 10 (see FIG. 5). For example, an Si substrate is used for the substrate 10.

Next, the channel layer 12 is formed onto the buffer layer 11 (see FIG. 5). For example, GaN is used for the channel layer 12. GaN is formed by using an epitaxial growth method.

Next, the barrier layer 15 is formed onto the channel layer 12 (see FIG. 5). For example, u-AlGaN is used for the barrier layer 15. For example, Al_{0.3}-Ga_{0.7}N mixed crystal is used for the barrier layer 15. The barrier layer 15 is formed by using an epitaxial growth method.

Upon the formation of the barrier layer 15, the two-dimensional electronic gas 13 is generated at the channel layer 12 near the barrier layer 15.

As illustrated in FIG. 5, a mask 30 is formed onto the barrier layer 15. For example, the aforementioned insulating material is used for the mask 30.

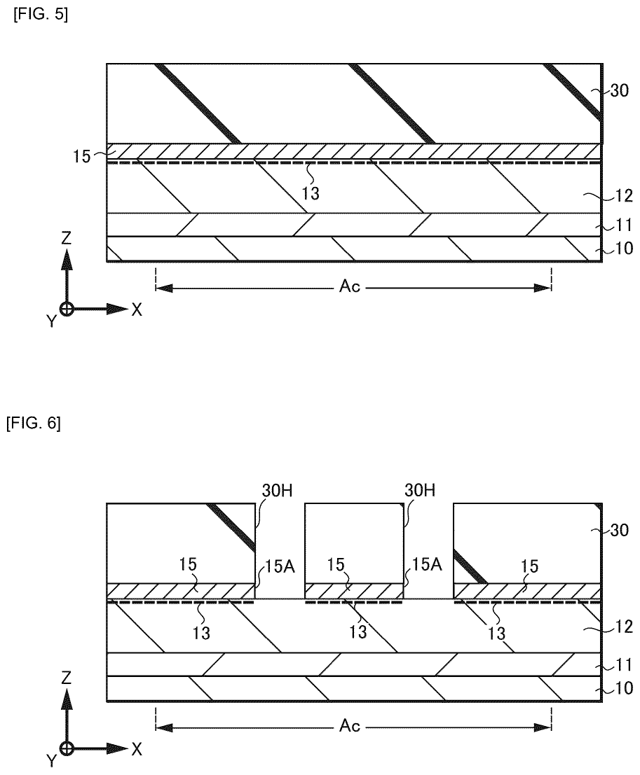

Next, the mask 30 is patterned. Consequently, an opening 30H is formed on part of the mask 30 (see FIG. 6). A photolithography technique and an etching technique are used for the patterning.

As illustrated in FIG. 6, the mask 30 is used to pattern the barrier layer 15 that is exposed through the opening 30H. Through the patterning, the gate barrier opening 15A that exposes the surface of the channel layer 12 is formed at the barrier layer 15.

The etching technique is used for the patterning. Used as the etching technique is wet etching that makes it possible to ensure an etching selection ratio between the channel layer 12 and the barrier layer 15. The use of the wet etching makes it possible to selectively remove the barrier layer 15 without over-etching the surface of the channel layer 12. Moreover, since dry etching is not used, no etching damage occurs on the surface of the channel layer 12.

Note that dry etching is first used and then wet etching is used for the patterning. Moreover, patterning may be performed only through dry etching as long as damage is kept low.

Next, the mask 30 is removed. Note that instead of removing the mask 30, the mask 30 may be used as a protection film in the following processes.

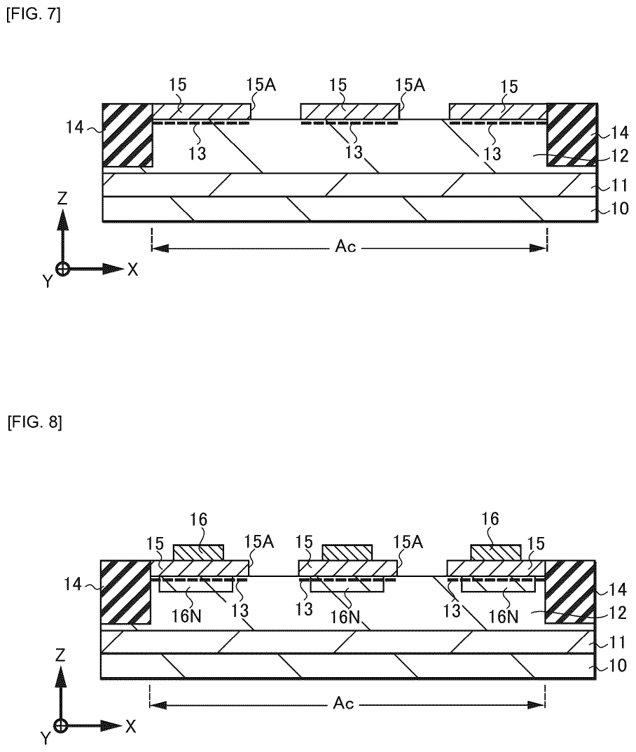

As illustrated in FIG. 7, the device isolation region 14 is formed around the active region Ac. For example, as a result of implanting p-type impurities into the barrier layer 15 and the channel layer 12, the device isolation region 14 is formed as a highly resistive inactive region. Consequently, the active region Ac of an island shape surrounded by the device isolation region 14 is formed.

Note that the device isolation region 14 may be formed after the formation of the main electrodes 16 or after the formation of the gate electrode 18.

As illustrated in FIG. 8, the pair of main electrodes 16 is formed in mutually separated regions on the barrier layer 15. The main electrode 16 is formed by sequentially depositing Ti, Al, Ni, and Au by using, for example, a mask deposition method.

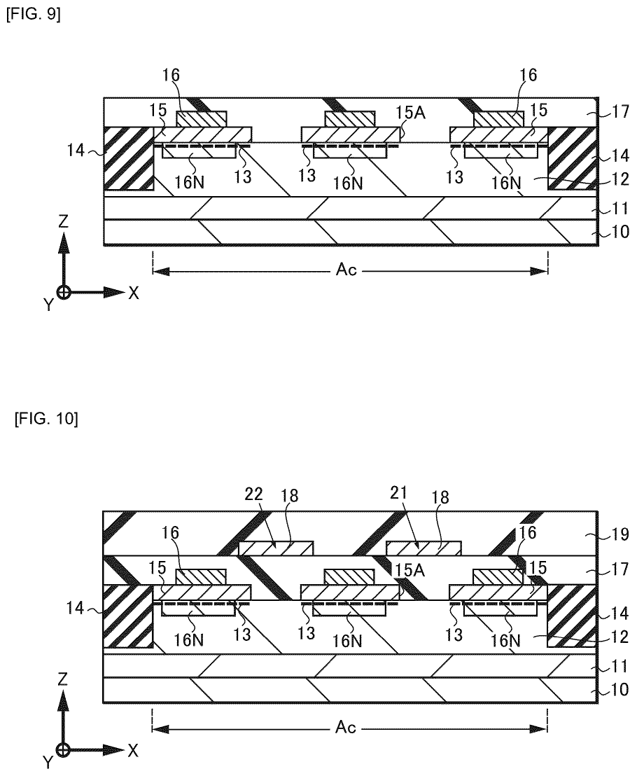

As illustrated in FIG. 9, the insulator 17 is formed covering the main electrodes 16. The insulator 17 is also formed onto the barrier layer 15 and onto the channel layer 12 that is exposed through the gate barrier opening 15A. With the aforementioned manufacturing method, the insulator 17 is formed by, for example, SiO₂. The SiO₂ is formed by using, for example, a CVD method.

Next, the gate electrode 18 is formed onto the insulator 17 in a region overlapping the gate barrier opening 15A (see FIG. 10). The gate electrode 18 is formed by sequentially depositing Ni and Au by using, for example, a mask deposition method.

As illustrated in FIG. 10, the interlayer insulator 19 is formed that covers the gate electrode 18. With the aforementioned manufacturing method, the interlayer insulator 19 is formed by using, for example, SiO₂. The SiO₂ is formed by using, for example, a CVD method.

Next, the connection hole 19H is formed in the interlayer insulator 19 (see FIGS. 2 to 4). Subsequently, as illustrated in FIGS. 2 to 4, the wiring 6 is formed onto the interlayer insulator 19. The wiring 6 is coupled to each of the main electrode 16 and the gate electrode 18 via the connection hole 19H.

Upon ending of the series of manufacturing processes, the first field effect transistor 21 to the fourth field effect transistor 24 of the electrostatic discharge protection circuit 2 are formed, completing the semiconductor device 1 according to the first embodiment.

### Operation of Electrostatic Discharge Protection Circuit 2

Protection operation of the electrostatic discharge protection circuit 2 will be briefly described with reference to FIGS. 1 to 4 described above. The description here refers to the protection operation of the first multi-gate transistor MT1. The protection operation of the second multi-gate transistor MT2 is the same as the protection operation of the first multi-gate transistor MT1 and thus will be omitted from the description.

The first multi-gate transistor MT1 includes electrical series-coupling between the first terminal 3 and the second terminal 4. Specifically, between the first terminal 3 and the second terminal 4, a capacitance C1 between the one main electrode 16 and the gate electrode 18 of the first field effect transistor 21 and a capacitance C2 between the one main electrode 16 and the gate electrode 18 of the second field effect transistor 22 are electrically coupled in series (see FIG. 2). The capacitances C1 and C2 are equivalent to each other.

It is assumed here that surge is applied to the first terminal 3. The surge is instantly pressure-divided to each of the capacitances C1 and C2. Following the aforementioned pressure division, the first field effect transistor 21 and the second field effect transistor 22 of the first multi-gate transistor MT1 turn into an ON state since the same voltage is applied between the one main electrode 16 and the gate electrode 18.

Thus, the surge applied to the first terminal 3 flows to the first field effect transistor 21 and the second field effect transistor 22 and is absorbed by the second terminal 4.

Note that increasing the gate width Wg of the first field effect transistor 21 to the fourth field effect transistor 24 in the electrostatic discharge protection circuit 2 permits further improvement in protection resistance.

### Characteristics of Electrostatic Discharge Protection Circuit 2

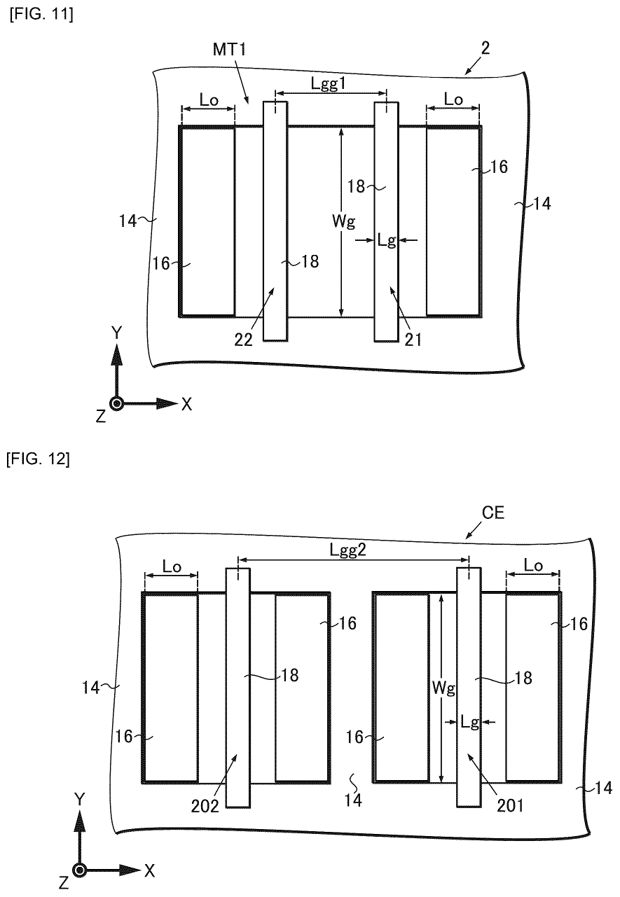

FIG. 11 illustrates one example of a schematic planar structure of the first multi-gate transistor MT1 of the electrostatic discharge protection circuit 2 according to the first embodiment. FIG. 12 illustrates one example of a schematic planar structure of a stack type transistor of an electrostatic discharge protection circuit CE according to Comparative Example 1.

As illustrated in FIG. 11, the first field effect transistor 21 and the second field effect transistor 22 are disposed in a direction of arrow X, sharing the main electrodes 16 in the first multi-gate transistor MT1 of the electrostatic discharge protection circuit 2 according to the first embodiment.

Here, the gate length Lg of each of the first field effect transistor 21 and the second field effect transistor 22 is set at, for example, 1 μm. Moreover, an ohmic length Lo of the main electrode 16 matching the gate length Lg of each of the first field effect transistor 21 and the second field effect transistor 22 is set at, for example, 1 μm. An inter-gate distance Lgg1 between the gate electrode 18 of the first field effect transistor 21 and the gate electrode 18 of the second field effect transistor 22 is set at, for example, 2 μm.

On the contrary, as illustrated in FIG. 12, a field effect transistor 201 and a field effect transistor 202 are disposed in a direction of arrow X with a device isolation region 14 interposed therebetween in the stack-type transistor of the electrostatic discharge protection circuit CE according to Comparative Example 1.

Here, a gate length Lg of each of the field effect transistor 201 and the field effect transistor 202 is set at, for example, 1 μm. Moreover, an ohmic length Lo of a main electrode 16 of each of the field effect transistor 201 and the field effect transistor 202 is set at, for example, 1 μm. An inter-gate distance Lgg2 between a gate electrode 18 of the field effect transistor 201 and a gate electrode 18 of the field effect transistor 202 is a value obtained by adding, to the inter-gate distance Lgg1, dimensions of the one main electrode 16 and the device isolation region 14 in the direction of arrow X.

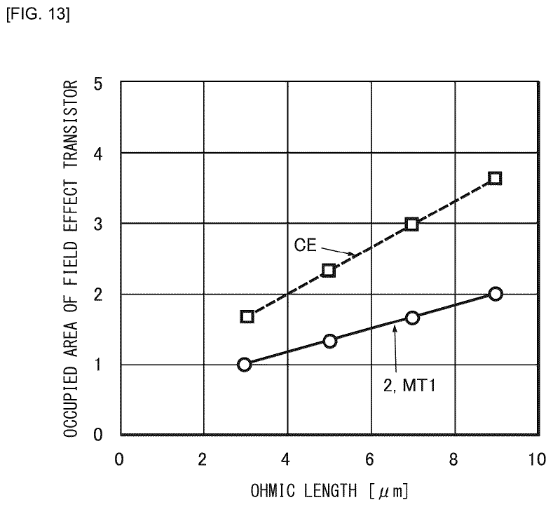

FIG. 13 is a graph comparing an occupied area of the electrostatic discharge protection circuit 2 according to the first embodiment and an occupied area of the electrostatic discharge protection circuit CE according to Comparative Example 1. A horizontal axis represents the ohmic length Lo [μm]. A vertical axis represents the respective occupied areas of the electrostatic discharge protection circuit 2 and the electrostatic discharge protection circuit CE. Here, where a total ohmic length Lo of the first field effect transistor 21 and the second field effect transistor 22 in the first multi-gate transistor MT1 of the electrostatic discharge protection circuit 2 is set at 3 μm, the occupied area is standardized at a value of “1”.

As illustrated in FIG. 13, the occupied area increases with an increase in the ohmic length Lo of, for example, the field effect transistor 201 and under the presence of the device isolation region 14 in the electrostatic discharge protection circuit CE according to Comparative Example 1.

The occupied area also increases with an increase in the ohmic length Lo of, for example, the first field effect transistor 21 in the electrostatic discharge protection circuit 2 according to the first embodiment. However, compared to an increase rate of the occupied area of the electrostatic discharge protection circuit CE according to Comparative Example 1, an increase rate of the occupied area of the electrostatic discharge protection circuit 2 according to the first embodiment is as small as about 30%. In other words, compared to the occupied area of the electrostatic discharge protection circuit CE according to Comparative Example 1, the occupied area of the electrostatic discharge protection circuit 2 according to the first embodiment is reduced regardless of an increase or decrease in the ohmic length Lo.

### Effects

The semiconductor device 1 according to the first embodiment includes the multi-gate transistor MT, the first terminal 3, and the second terminal 4, as illustrated in FIGS. 1 to 4.

The multi-gate transistor MT includes the first field effect transistor 21 to the fourth field effect transistor 24 each having the pair of main electrodes 16 and the gate electrode 18 disposed between the pair of main electrodes 16. The plurality of field effect transistors including the first field effect transistor 21 to the fourth field effect transistor 24 are electrically coupled in series, sharing the main electrodes 16.

Here, the multi-gate transistor MT includes the first multi-gate transistor MT1 and the second multi-gate transistor MT2. The first multi-gate transistor MT1 is formed by the first field effect transistor 21 and the second field effect transistor 22. Moreover, the second multi-gate transistor MT2 is formed by the third field effect transistor 23 and the fourth field effect transistor 24. The first multi-gate transistor MT1 and the second multi-gate transistor MT2 have the same configuration, and thus the first multi-gate transistor MT1 will be mainly described and the second multi-gate transistor MT2 will be described as appropriate.

The first terminal 3 is electrically coupled to the one main electrode 16 of the first field effect transistor 21 at one end of the series-coupled field effect transistors of the first multi-gate transistor MT1. The first terminal 3 receives a signal.

The second terminal 4 is electrically coupled to the other main electrode 16 of the second field effect transistor 22 at the other end of the series-coupled field effect transistors of the first multi-gate transistor MT1. The second terminal 4 receives supply of a fixed potential.

Then the gate electrode 18 of at least one of the first field effect transistor 21 or the second field effect transistor 22 of the first multi-gate transistor MT1 is electrically coupled to the other main electrode 16 of the first field effect transistor 21 or the second field effect transistor 22.

The first multi-gate transistor MT1 (and the second multi-gate transistor MT2) form the electrostatic discharge protection circuit 2.

In the semiconductor device 1 configured as described above, the electrostatic discharge protection circuit 2 includes the multi-gate transistor MT and the main electrodes 16 of the first field effect transistor 21 to the fourth field effect transistor 24 of the multi-gate transistor MT are shared. Thus, as illustrated in FIGS. 11 to 13, it is possible to reduce the occupied area of the electrostatic discharge protection circuit 2. In addition, since the plurality of field effect transistors including the first field effect transistor 21 to the fourth field effect transistor 24 are coupled in series in the electrostatic discharge protection circuit 2 configured as described above, it is possible to improve an electrostatic breakdown voltage. That is, it is possible to improve the electrostatic breakdown voltage while improving the degree of integration in the semiconductor device 1.

Moreover, as illustrated in FIGS. 1 to 4, in the semiconductor device 1, all the gate electrodes 18 of the first field effect transistor 21 to the fourth field effect transistor 24 of the multi-gate transistor MT forming the electrostatic discharge protection circuit 2 are electrically coupled to the other main electrodes 16 of the first field effect transistor 21 to the fourth field effect transistor 24.

Thus, it is possible to instantly absorb surge upon surge input, thus making it possible to further improve the electrostatic breakdown voltage in the electrostatic discharge protection circuit 2.

Moreover, in the semiconductor device 1 as illustrated in FIGS. 2 to 4, the first field effect transistor 21 to the fourth field effect transistor 24 of the electrostatic discharge protection circuit 2 each have the gate electrode 18 formed at the channel layer 12 as the semiconductor layer with the insulator 17 as the gate insulating film interposed therebetween. That is, the first field effect transistor 21 to the fourth field effect transistor 24 include the gate insulating field effect transistors.

The insulator 17 has a film thickness set at 20 nm or more in terms of conversion into an oxide film thickness.

Thus, it is possible to increase an ON current of each of the first field effect transistor 21 to the fourth field effect transistor 24 in the electrostatic discharge protection circuit 2.

Moreover, in the electrostatic discharge protection circuit 2 in the semiconductor device 1 as illustrated in FIGS. 2 to 4, the gate electrode 18 and the other main electrode 16 are coupled via the wiring 6 having a smaller specific resistance value than a specific resistance value of each of the gate electrode 18 and the main electrode 16.

Thus, it is possible to improve a speed of the protection operation of the electrostatic discharge protection circuit 2. In addition, no resistor is inserted at a connection path between the gate electrode 18 and the main electrode 16, thus making it possible to further reduce the occupied area of the electrostatic discharge protection circuit 2.

Moreover, in the electrostatic discharge protection circuit 2 in the semiconductor device 1 as illustrated in FIGS. 2 to 4, the main electrode 16 and the wiring 6 are coupled by ohmic bonding.

In addition, the main electrode 16 includes an ohmic electrode disposed at the channel layer 12 of, for example, the first field effect transistor 21. The ohmic electrode is electrically coupled to the channel layer 12 via the high impurity density region 16N. The high impurity density region 16N is disposed at the channel layer 12, has the same conductivity type as the carriers flowing to the channel layer 12, and has higher impurity density than the channel layer 12.

Furthermore, the gate electrode 18 and the other main electrode 16 are coupled with a resistance value of smaller than or equal to 100 Ω, more specifically, smaller than or equal to 10 Ω.

It is possible to improve the speed of the protection operation of the electrostatic discharge protection circuit 2 in the semiconductor device 1 configured as described above.

Moreover, in the semiconductor device 1 as illustrated in FIGS. 2 and 3, the first field effect transistor 21 to the fourth field effect transistor 24 of the electrostatic discharge protection circuit 2 are configured to include a nitride semiconductor. In addition, as illustrated in FIG. 1, a DC signal is inputted to the first terminal 3 and a reference potential (or operating power supply potential) of a high frequency circuit is supplied to the second terminal 4. Examples of the high frequency circuit include a power device, a high frequency device, and so on.

Thus, it is possible to realize the electrostatic discharge protection circuit 2 suitable for the semiconductor device 1 that forms the power device, the high frequency device, or the like.

Note that the first embodiment is described, referring to the electrostatic discharge protection circuit 2 disposed on a signal input side of the semiconductor device 1. The present technology is applicable to the electrostatic discharge protection circuit 2 disposed on a signal output side of the semiconductor device 1. In the case, the DC signal from the internal circuit 5 is outputted to the first terminal 3.

Moreover, in the first embodiment, the electrostatic discharge protection circuit 2 forms the multi-gate transistor MT with the first multi-gate transistor MT1 and the second multi-gate transistor MT2 having symmetrical structures. In the case, it is possible to enlarge the gate width dimension, thus making it possible to improve current capability. With the present technology, as long as it is possible to ensure a sufficient gate length dimension, the electrostatic discharge protection circuit 2 may form the multi-gate transistor MT by either of the first multi-gate transistor MT1 or the second multi-gate transistor MT2.

### 2. Second Embodiment

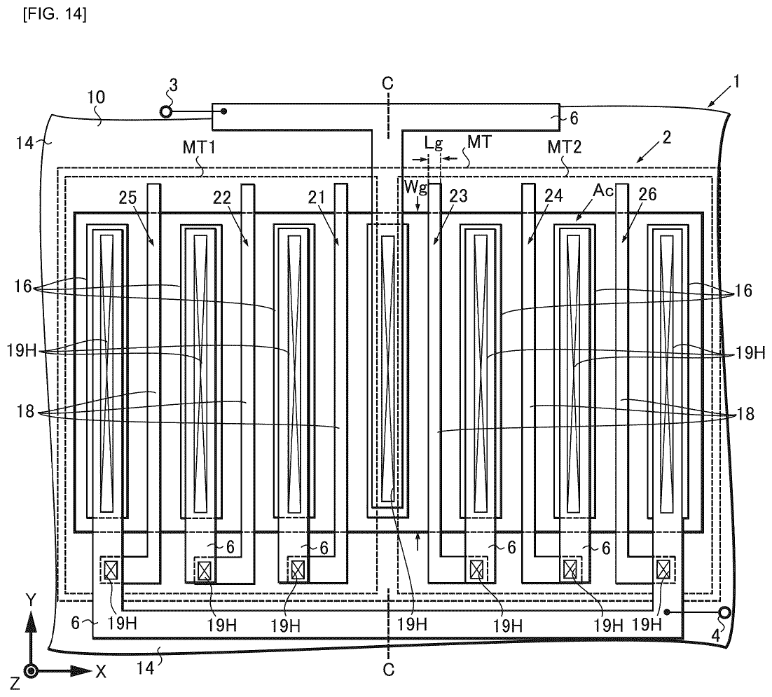

A semiconductor device 1 and an electrostatic discharge protection circuit 2 according to the second embodiment will be described with reference to FIGS. 14 to 17.

Note that in the second embodiment and embodiments described thereafter, the same components or substantially the same components as those of the first embodiment are provided with the same reference numerals, and overlapping description will be omitted.

### Detailed Device Configuration of Semiconductor Device 1 and Electrostatic Discharge Protection Circuit 2

FIG. 14 illustrates one example of a planar configuration of the electrostatic discharge protection circuit 2 loaded in the semiconductor device 1.

As is the case with the electrostatic discharge protection circuit 2 according to the first embodiment, the electrostatic discharge protection circuit 2 according to the second embodiment includes a multi-gate transistor MT. The multi-gate transistor MT is formed by a first multi-gate transistor MT1 and a second multi-gate transistor MT2.

The multi-gate transistor MT1 further includes a fifth field effect transistor 25 in addition to a first field effect transistor 21 and a second field effect transistor 22. Specifically, the first multi-gate transistor MT1 shares main electrodes 16 and includes the three transistors including the first field effect transistor 21, the second field effect transistor 22, and the fifth field effect transistor 25 that are electrically coupled in series between a first terminal 3 and a second terminal 4.

A gate electrode 18 of each of the first field effect transistor 21, the second field effect transistor 22, and the fifth field effect transistor 25 is electrically coupled to another corresponding main electrode 16 via a wiring 6.

The second multi-gate transistor MT2 further includes a sixth field effect transistor 26 in addition to a third field effect transistor 23 and a fourth field effect transistor 24. Specifically, the second multi-gate transistor MT2 shares main electrodes 16 and includes the three field effect transistors including the third field effect transistor 23, the fourth field effect transistor 24, and the sixth field effect transistor 26 that are electrically coupled in series between the first terminal 3 and the second terminal 4.

The gate electrodes 18 of each of the third field effect transistor 23, the fourth field effect transistor 24, and the sixth field effect transistor 26 are electrically coupled to another corresponding main electrodes 16 via wirings 6.

The second multi-gate transistor MT2 is formed into a shape line symmetrical with respect to the first multi-gate transistor MT1 with a center line C-C as a center.

Components other than those described above are the same or substantially the same as the components of the semiconductor device 1 and the electrostatic discharge protection circuit 2 according to the first embodiment described above, and are thus omitted here from the description.

### Characteristics of Electrostatic Discharge Protection Circuit 2

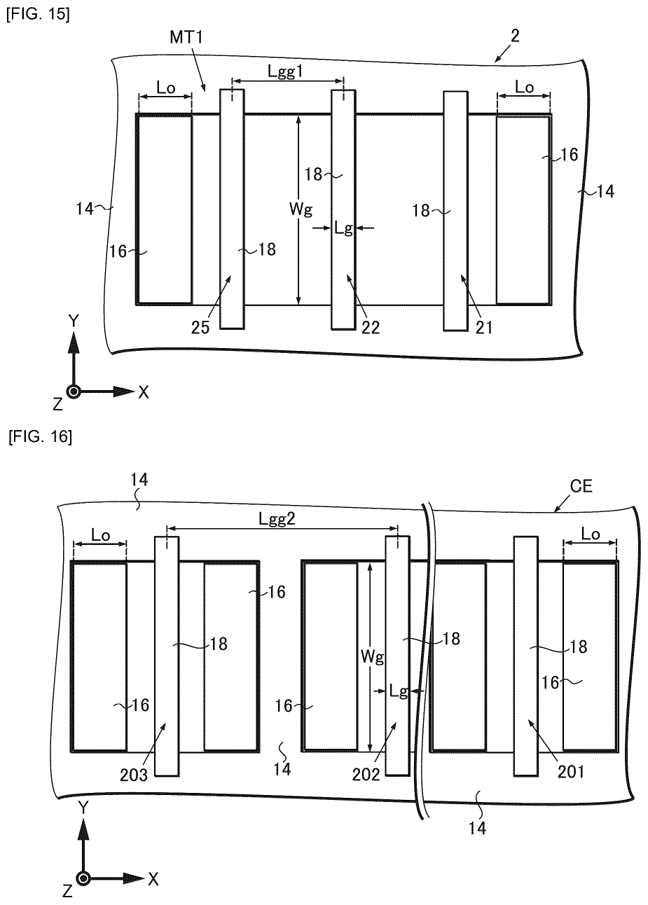

FIG. 15 illustrates one example of a schematic planar structure of the first multi-gate transistor MT1 of the electrostatic discharge protection circuit 2 according to the second embodiment. FIG. 16 illustrates one example of a schematic planar structure of a stack type transistor of an electrostatic discharge protection circuit CE according to Comparative Example 2.

As illustrated in FIG. 15, the first field effect transistor 21, the second field effect transistor 22, and the fifth field effect transistor 25 are disposed in a direction of arrow X in the first multi-gate transistor MT1 of the electrostatic discharge protection circuit 2 according to the second embodiment. The first field effect transistor 21, the second field effect transistor 22, and the fifth field effect transistor 25 share the main electrodes 16.

As is the case with the electrostatic discharge protection circuit 2 according to the first embodiment, a gate lengths Lg of each of the first field effect transistor 21, the second field effect transistor 22, and the fifth field effect transistor 25 are set at, for example, 1 μm. Moreover, an ohmic length Lo of the main electrode 16 matching a gate length Lg of each of the first field effect transistor 21, the second field effect transistor 22, and the fifth field effect transistor 25 is set at, for example, 1 μm. An inter-gate distance Lgg1 between the gate electrode 18 of the first field effect transistor 21 and the gate electrode 18 of the second field effect transistor 22 is set at, for example, 2 μm. Similarly, an inter-gate distance Lgg1 between the gate electrode 18 of the second field effect transistor 22 and the gate electrode 18 of the fifth field effect transistor 25 is set at, for example, 2 μm.

On the contrary, as illustrated in FIG. 16, the stack-type transistor of the electrostatic discharge protection circuit CE according to Comparative Example 2 includes three field effect transistors including a field effect transistor 201, a field effect transistor 202, and a field effect transistor 203. The field effect transistor 201, the field effect transistor 202, and the field effect transistor 203 are arrayed in a direction of arrow X with a device isolation region 14 interposed therebetween.

Here, a gate lengths Lg of each of the field effect transistor 201, the field effect transistor 202, and the field effect transistor 203 are set at, for example, 1 μm. Moreover, an ohmic length Lo of the main electrode 16 of each of the field effect transistor 201, the field effect transistor 202, and the field effect transistor 203 is set at, for example, 1 μm. An inter-gate distance Lgg2 between a gate electrode 18 of the field effect transistor 201 and a gate electrode 18 of the field effect transistor 202 is a value obtained by adding, to the inter-gate distance Lgg1, dimensions of one main electrode 16 and the device isolation region 14 in the direction of arrow X. Similarly, an inter-gate distance Lgg2 between the gate electrode 18 of the field effect transistor 202 and a gate electrode 18 of the field effect transistor 203 is a value obtained by adding, to the inter-gate distance Lgg1, the dimensions of the one main electrode 16 and the device isolation region 14 in the direction of arrow X.

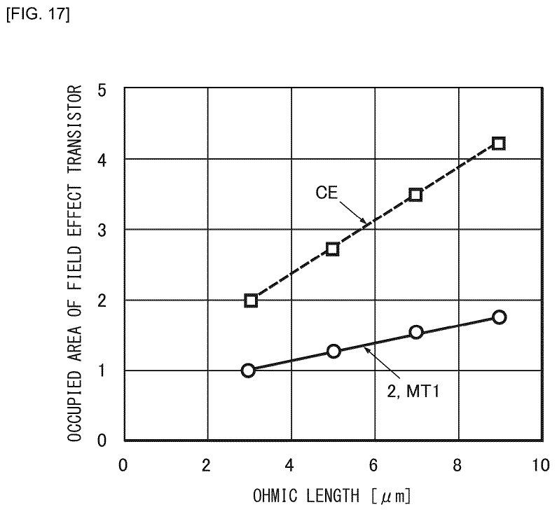

FIG. 17 is a graph comparing an occupied area of the electrostatic discharge protection circuit 2 according to the second embodiment and an occupied area of the electrostatic discharge protection circuit CE according to Comparative Example 2. A horizontal axis represents an ohmic length Lo [μm]. A vertical axis represents the occupied area of each of the electrostatic discharge protection circuit 2 and the electrostatic discharge protection circuit CE. Here, when a total ohmic length Lo of the first field effect transistor 21, the second field effect transistor 22, and the fifth field effect transistor 25 in the first multi-gate transistor MT1 of the electrostatic discharge protection circuit 2 is set at 3 μm, the occupied area is standardized at a value of “1”.

As illustrated in FIG. 17, in the electrostatic discharge protection circuit CE according to Comparative Example 2, the occupied area increases with an increase in the ohmic length Lo of, for example, the field effect transistor 201.

The occupied area increases with an increase in the ohmic length Lo of, for example, the first field effect transistor 21 even in the electrostatic discharge protection circuit 2 according to the second embodiment. However, compared to an increase rate of the occupied area of the electrostatic discharge protection circuit CE according to Comparative Example 2, an increase rate of the occupied area of the electrostatic discharge protection circuit 2 according to the second embodiment is as small as about 50%. In other words, compared to the occupied area of the electrostatic discharge protection circuit CE according to Comparative Example 2, the occupied area of the electrostatic discharge protection circuit 2 according to the second embodiment is reduced regardless of an increase or decrease in the ohmic length Lo.

### Effects

With the semiconductor device 1 and the electrostatic discharge protection circuit 2 according to the second embodiment, it is possible to provide the same effects as the effects providable by the semiconductor device 1 and the electrostatic discharge protection circuit 2 according to the first embodiment described above.

Moreover, as lustrated in FIG. 14, the electrostatic discharge protection circuit 2 shares the main electrodes 16 between the first terminal 3 and the second terminal 4 and includes the six field effect transistors including the first field effect transistor 21 to the sixth field effect transistor 26. This makes it possible to further improve the electrostatic breakdown voltage and also reduce the occupied area of the electrostatic discharge protection circuit 2 as illustrated in FIGS. 15 to 17.

Furthermore, in the electrostatic discharge protection circuit 2, the multi-gate transistor MT is formed with a larger number of serial connections of the field effect transistors than a number of serial connections of the field effect transistors of the electrostatic discharge protection circuit 2 according to the first embodiment. Even with an increase in the number of serial connections, it is possible to reduce the occupied area of the electrostatic discharge protection circuit 2, compared to the electrostatic discharge protection circuit CE according to Comparative Example 2. Note that, with the present technology, the first multi-gate transistor MT1 of the electrostatic discharge protection circuit 2 may be formed with four or more serial connections.

Note that, as is the case with the first embodiment, the electrostatic discharge protection circuit 2 in the second embodiment is formed by the first multi-gate transistor MT1 and the second multi-gate transistor MT2 having symmetrical structures. With the present technology, as long as it is possible to ensure a sufficient gate width dimension, the multi-gate transistor MT of the electrostatic discharge protection circuit 2 may be formed by one of the first multi-gate transistor MT1 and the second multi-gate transistor MT2.

### 3. Third Embodiment

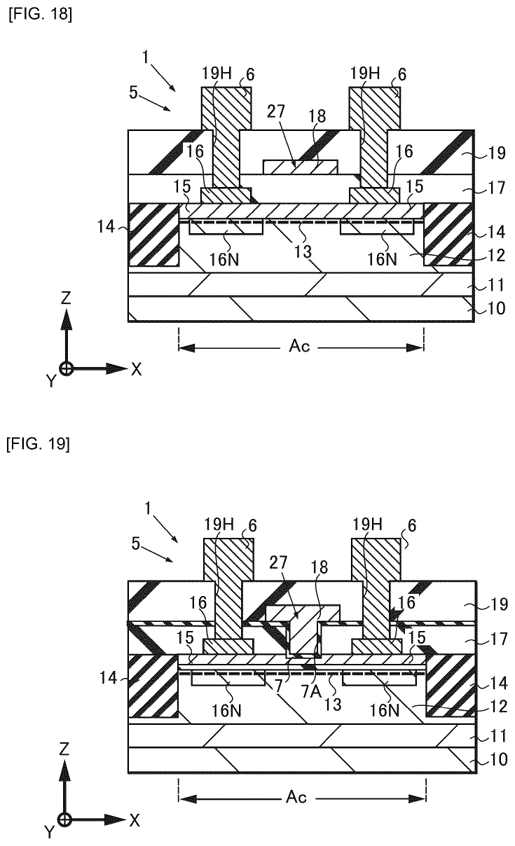

A semiconductor device 1 and an internal circuit 5 according to the third embodiment of the present disclosure will be described with reference to FIG. 18.

### Detailed Device Configuration of Semiconductor Device 1 and Internal Circuit 5

FIG. 18 illustrates one example of a cross-sectional configuration of the internal circuit 5.

In the semiconductor device 1 according to the third embodiment, the first field effect transistor 21 to the fourth field effect transistor 24 of the multi-gate transistor MT of the electrostatic discharge protection circuit 2 according to the first embodiment and a field effect transistor 27 of the internal circuit 5 (see FIG. 1) are monolithically formed.

More specifically describing, the field effect transistor 27 basically includes the same structure as the structures of the first field effect transistor 21 to the fourth field effect transistor 24 and includes a depression type field effect transistor (DFET) that demonstrates normally-on operation.

Even more specifically describing, no gate barrier opening 15A is provided at the field effect transistor 27 of an internal circuit 5 (see FIG. 3). That is, a gate electrode 18 is disposed at a channel layer 12 with a barrier layer 15 and an insulator 17 interposed therebetween at the field effect transistor 27. The “barrier layer 15” here corresponds to a “semiconductor layer” according to the present technology.

In an OFF state, two-dimensional electronic gas 13 is formed at a position of the channel layer 12 overlapping the gate electrode 18 in plan view and side view.

Components other than those described above are the same or substantially the same as the components of the semiconductor device 1 and the electrostatic discharge protection circuit 2 according to the first embodiment, and thus are omitted here from the description.

Note that the internal circuit 5 according to the third embodiment may include the field effect transistor 27 that is monolithically formed with the first field effect transistor 21 to the sixth field effect transistor 26 of the multi-gate transistor MT of the electrostatic discharge protection circuit 2 according to the second embodiment.

### Effects

In the semiconductor device 1 and the internal circuit 5 according to the third embodiment, it is possible to provide, effects similar to the effects providable by the semiconductor device 1 and the electrostatic discharge protection circuit 2 according to the first embodiment or the second embodiment.

Moreover, as illustrated in FIG. 18, the field effect transistor 27 of the internal circuit 5 is monolithically formed with the multi-gate transistor MT of the electrostatic discharge protection circuit 2 according to the first embodiment or the second embodiment described above. That is, it is possible to standardize most of the components and manufacturing processes in the internal circuit 5 and the electrostatic discharge protection circuit 2, thus making it possible to form the semiconductor device 1 with a simple structure and by a simple manufacturing method.

### 4. Forth Embodiment

A semiconductor device 1 and an internal circuit 5 according to the fourth embodiment of the present disclosure will be described with reference to FIG. 19.

### Detailed Device Configuration of Semiconductor Device 1 and Internal Circuit 5

FIG. 19 illustrates one example of a cross-sectional configuration of the internal circuit 5.

The internal circuit 5 according to the fourth embodiment includes a field effect transistor 27, as is the case with the internal circuit 5 according to the third embodiment. A t-type gate structure is adopted for the field effect transistor 27.

More specifically describing, no gate barrier opening 15A is disposed at a barrier layer 15 in the field effect transistor 27 of the internal circuit 5, as is the case with the field effect transistor 27 of the internal circuit 5 according to the third embodiment (see FIG. 3). On the other hand, a gate opening 7A penetrating through an insulator 17 in a film thickness direction is disposed at a position overlapping a gate electrode 18. Then at least a gate insulating film 7 is disposed at the barrier layer 15 exposed through the gate opening 7A. That is, the gate electrode 18 is disposed in the gate opening 7A with the gate insulating film 7 interposed at the barrier layer 15 in the field effect transistor 27. The “barrier layer 15” here corresponds to a “semiconductor layer” according to the present technology.

A dimension of manufacturing alignment allowance for the gate opening 7A is added to the gate electrode 18. Thus, the gate electrode 18 is formed with greater dimensions in a direction along a gate length Lg and a direction along a gate width Wg than an opening dimension of the gate opening 7A. That is, a cross section of the gate electrode 18 is formed into a T-shape in side view.

Components other than those described above are the same or substantially the same as the components of the semiconductor device 1 and the internal circuit 5 according to the third embodiment described above, and are thus omitted here from the description.

Note that the internal circuit 5 according to the fourth embodiment may include the field effect transistor 27 monolithically formed with the first field effect transistor 21 to the sixth field effect transistor 26 of the multi-gate transistor MT of the electrostatic discharge protection circuit 2 according to the second embodiment.

### Effects

With the semiconductor device 1 and the internal circuit 5 according to the fourth embodiment, it is possible to provide effects similar to the effects providable by the semiconductor device 1 and the internal circuit 5 according to the third embodiment described above.

Moreover, as illustrated in FIG. 19, the field effect transistor 27 of the internal circuit 5 is monolithically formed with the multi-gate transistor MT of the electrostatic discharge protection circuit 2 according to the first embodiment or the second embodiment described above. That is, it is possible to standardize most of the components and manufacturing processes at the internal circuit 5 and the electrostatic discharge protection circuit 2, thus making it possible to form the semiconductor device 1 with a simple structure and by a simple manufacturing method.

### 5. Fifth Embodiment

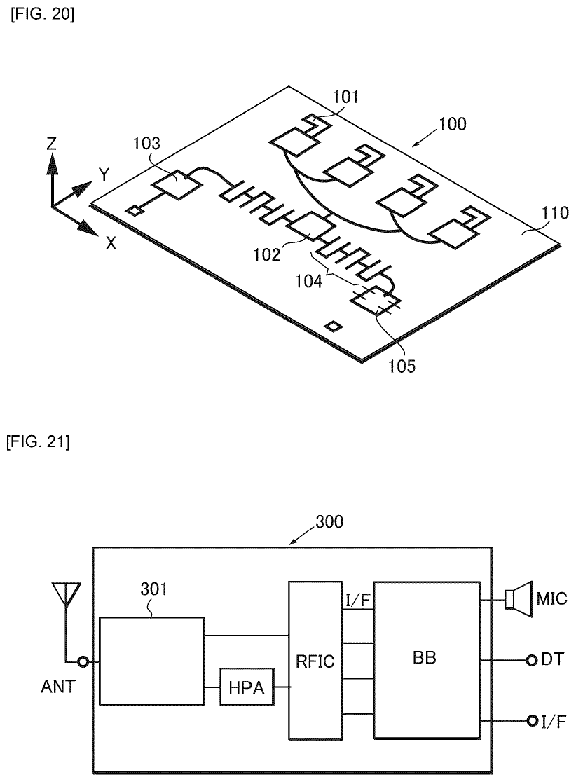

A semiconductor module 100 according to the fifth embodiment will be described with reference to FIG. 20. F 20 illustrates a schematic structure of the semiconductor module 100 according to the fifth embodiment.

### Configuration of Semiconductor Module 100

The semiconductor module 100 according to the fifth embodiment is an antenna integrated module having, for example, an edge antenna 101 disposed in an array and front-end components, both of which are mounted as one module on a substrate 110. The front-end components include, for example, a switch 102, a low noise amplifier 103, a band pass filter 104, and a power amplifier 105. The semiconductor module 100 is usable as, for example, a communication transceiver.

The semiconductor module 100 includes any of the semiconductor devices 1 according to the first to fourth embodiments as a transistor that includes, for example, a switch 102, a low noise amplifier 103, or a power amplifier 105.

### Effects

Since the semiconductor module 100 according to the fifth embodiment includes the semiconductor device 1, it is possible to realize even higher speed, higher efficiency and lower power consumption of wireless communication.

Moreover, the electrostatic discharge protection circuit 2 according to any of the first to fourth embodiments is loaded on the semiconductor device 1. Thus, it is possible to realize reduction in the occupied area of the electrostatic discharge protection circuit 2 while improving electrostatic breakdown protection resistance in the semiconductor module 100.

### 6. Sixth Embodiment

A wireless communication device 300 according to the sixth embodiment of the present disclosure will be described with reference to FIG. 21. FIG. 21 illustrates a schematic block configuration of the wireless communication device 300 according to the sixth embodiment.

### Configuration of Wireless Communication Device 300

The wireless communication device 300 according to the sixth embodiment includes an antenna ANT, an antenna switch circuit 301, a high power amplifier HPA, a radio frequency integrated circuit RFIC, a base band section BB, a voice output section MIC, a data output section DT, and an interface section I/F. The interface section I/F includes, for example, a wireless LAN (Local Area Network: W-LAN:), Bluetooth (registered trademark), and so on. The wireless communication device 300 is a mobile phone system that has many functions such as, for example, voice or data communication or LAN connection.

The wireless communication device 300 includes the semiconductor device 1 according to any of the first to fourth embodiments as a transistor that includes, for example, the antenna switch circuit 301; the high-power amplifier HPA, the radio frequency integrated circuit RFIC, or the base band section BB.

### Effects

Since the wireless communication device 300 according to the sixth embodiment includes the semiconductor device 1, it is possible to realize even higher speed, higher efficiency, and lower power consumption of wireless communication. Thus, in a case where the wireless communication device 300 is a portable communication terminal, it is possible to further extend usage time in the wireless communication device 300, thus making it possible to further improve portability.

Moreover, the electrostatic discharge protection circuit 2 according to any of the first to fourth embodiments is loaded on the semiconductor device 1. Thus, it is possible to realize reduction in the occupied area of the electrostatic discharge protection circuit 2 while improving electrostatic breakdown protection resistance in the wireless communication device 300.

### 7. Other Embodiment

The present technology is not limited to the embodiments described above, and it is possible to make various modifications to the present technology within a scope not departing from the spirits thereof.

For example, the transistors are formed by a GaN semiconductor in the semiconductor devices according to the embodiments described above. The present technology is applicable to a semiconductor device that has a transistor formed by using a GaAs-based, InP-based, or SiGe-based compound semiconductor. Moreover, the present technology is also applicable to a semiconductor device that has a transistor formed by using a Si semiconductor.

Moreover, with the present technology, a Schottky junction field effect transistor may be used as the field effect transistor of the electrostatic discharge protection circuit.

As described above, the semiconductor device according to a first mode of the present disclosure includes the multi-gate transistor, the first terminal, and the second terminal. In the multi-gate transistor, the plurality of field effect transistors having the pair of main electrodes and the gate electrode disposed between the pair of main electrodes are electrically coupled in series while sharing the main electrodes. The first terminal is electrically coupled to the one main electrode of the field effect transistor at the one end of the series-coupled field effect transistors of the multi-gate transistor. The first terminal receives or outputs a signal. The second terminal is electrically coupled to the other main electrode of the field effect transistor at the other end of the series-coupled field effect transistors of the multi-gate transistor. The second terminal 4 receives supply of a fixed potential.

Here, the gate electrode of the at least one of the field effect transistors of the multi-gate transistor is electrically coupled to the other main electrode of the aforementioned field effect transistor. The multi-gate transistor is included in the electrostatic breakdown protection circuit.

Thus, since the electrostatic discharge protection circuit is disposed that has the plurality of field effect transistors electrically coupled in series between the first terminal and the second terminal, it is possible to improve an electrostatic breakdown protection voltage. In addition, since the plurality of field effect transistors form the multi-gate transistor and share the main electrodes, it is possible to reduce the occupied area of the electrostatic breakdown protection circuit.

The semiconductor module according to a second mode of the present disclosure includes the semiconductor device. The semiconductor device is the semiconductor device according to the first mode.

Thus, it is possible with the semiconductor module to provide effects similar to the effects provided by the semiconductor device according to the first mode.

The electronic apparatus according to a third mode includes the semiconductor device. The semiconductor device is the semiconductor device according to the first mode.

Thus, it is possible with the electronic apparatus to provide effects similar to the effects provided by the semiconductor device according to the first mode.

### Configuration of Present Technology

The present technology includes the following configuration. With the present technology with the following configuration, it is possible to improve the electrostatic breakdown protection voltage and reduce the occupied area of the electrostatic breakdown protection circuit in the semiconductor device, the semiconductor module, and the electronic apparatus.
(1)
A semiconductor device including:
a multi-gate transistor including a plurality of field effect transistors each having a pair of main electrodes and a gate electrode disposed between the pair of main electrodes, the field effect transistors being electrically coupled in series while sharing the main electrodes;
a first terminal being electrically coupled to one of the main electrodes of the field effect transistor at one end of the series-coupled field effect transistors of the multi-gate transistor, the first terminal receiving or outputting a signal; and
a second terminal being electrically coupled to another of the main electrodes of the field effect transistor at another end of the series-coupled field effect transistors of the multi-gate transistor, the second terminal receiving supply of a fixed potential, in which
the gate electrode of at least one of the field effect transistors of the multi-gate transistor is electrically coupled to the other main electrode of the same field effect transistor.
(2)
The semiconductor device according to the (1) described above, in which the gate electrode of each of all the field effect transistors of the multi-gate transistor is electrically coupled to the other main electrode of the same field effect transistor.
(3)
The semiconductor device according to the (1) or (2) described above, in which each field effect transistor includes a gate insulating field effect transistor forming the gate electrode with a gate insulating film interposed at a semiconductor layer.
(4)
The semiconductor device according to the (3) described above, in which the gate insulating film has a film thickness of 20 nm or more in terms of conversion into an oxide film thickness.
(5)
The semiconductor device according to any one of the (1) to (4) described above, in which the gate electrode and the other main electrode are coupled via a wiring with a smaller specific resistance value than a specific resistance value of the same gate electrode and the same main electrode.
(6)
The semiconductor device according to the (5) described above, in which the other main electrode and the wiring are coupled by ohmic junction.
(7)
The semiconductor device according to the (5) or (6) described above, in which
the other main electrode of each field effect transistor includes an ohmic electrode disposed at a channel layer of the same field effect transistor, and
the ohmic electrode is disposed at the channel layer, has a same conductive type as a carrier flowing to the same channel layer, and is electrically coupled to the channel layer via a high purity density region having higher impurity density than the channel layer.
(8)
The semiconductor device according to any one of the (5) to (7) described above, in which the gate electrode and the other main electrode are coupled at a resistance value of 100 Ω or below.
(9)
The semiconductor device according to any one of the (1) to (8) described above, in which each field effect transistor includes a nitride semiconductor.
(10)
The semiconductor device according to any one of the (1) to (9) described above, in which
the first terminal receives or outputs a DC signal, and
the second terminal receives supply of an operating power supply potential or a reference potential of a high frequency circuit.
(11)
The semiconductor device according to the (10) described above, in which the high frequency circuit includes a power amplifier.
(12)
The semiconductor device according to any one of the (1) to (11) described above, in which the multi-gate transistor is included in an electrostatic breakdown protection circuit.
(13)
A semiconductor module including a semiconductor device, in which
the semiconductor device includes
a multi-gate transistor including a plurality of field effect transistors each having a pair of main electrodes and a gate electrode disposed between the pair of main electrodes, the field effect transistors being electrically coupled in series while sharing the main electrodes,
a first terminal being electrically coupled to one of the main electrodes of the field effect transistor at one end of the series-coupled field effect transistors of the multi-gate transistor, the first terminal receiving or outputting a signal, and
a second terminal being electrically coupled to another of the main electrodes of the field effect transistor at another end of the series-coupled field effect transistors of the multi-gate transistor, the second terminal receiving supply of a fixed potential, in which
the gate electrode of at least one of the field effect transistors of the multi-gate transistor is electrically coupled to the other main electrode of the same field effect transistor.
(14)
An electronic apparatus including a semiconductor device, in which
the semiconductor device includes
a multi-gate transistor including a plurality of field effect transistors each having a pair of main electrodes and a gate electrode disposed between the pair of main electrodes, the field effect transistors being electrically coupled in series while sharing the main electrodes,
a first terminal being electrically coupled to one of the main electrodes of the field effect transistor at one end of the series-coupled field effect transistors of the multi-gate transistor, the first terminal receiving or outputting a signal, and
a second terminal being electrically coupled to another of the main electrodes of the field effect transistor at another end of the series-coupled field effect transistors of the multi-gate transistor, the second terminal receiving supply of a fixed potential, in which
the gate electrode of at least one of the field effect transistors of the multi-gate transistor is electrically coupled to the other main electrode of the same field effect transistor.

The present application claims the benefit of Japanese Priority Patent Application JP2022-129573 filed with the Japan Patent Office on Aug. 16, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A semiconductor device comprising:
a multi-gate transistor including a plurality of field effect transistors each having a pair of main electrodes and a gate electrode disposed between the pair of main electrodes, the field effect transistors being electrically coupled in series while sharing the main electrodes;
a first terminal being electrically coupled to one of the main electrodes of the field effect transistor at one end of the series-coupled field effect transistors of the multi-gate transistor, the first terminal receiving or outputting a signal; and
a second terminal being electrically coupled to another of the main electrodes of the field effect transistor at another end of the series-coupled field effect transistors of the multi-gate transistor, the second terminal receiving supply of a fixed potential, wherein
the gate electrode of at least one of the field effect transistors of the multi-gate transistor is electrically coupled to the other main electrode of the same field effect transistor.

2. The semiconductor device according to claim 1, wherein the gate electrode of each of all the field effect transistors of the multi-gate transistor is electrically coupled to the other main electrode of the same field effect transistor.

3. The semiconductor device according to claim 1, wherein each field effect transistor includes a gate insulating field effect transistor forming the gate electrode with a gate insulating film interposed at a semiconductor layer.

4. The semiconductor device according to claim 3, wherein the gate insulating film has a film thickness of 20 nm or more in terms of conversion into an oxide film thickness.

5. The semiconductor device according to claim 1, wherein the gate electrode and the other main electrode are coupled via a wiring with a smaller specific resistance value than a specific resistance value of the same gate electrode and the same main electrode.

6. The semiconductor device according to claim 5, wherein the other main electrode and the wiring are coupled by ohmic junction.

7. The semiconductor device according to claim 5, wherein
the other main electrode of each field effect transistor includes an ohmic electrode disposed at a channel layer of the same field effect transistor, and
the ohmic electrode is disposed at the channel layer, has a same conductive type as a carrier flowing to the same channel layer, and is electrically coupled to the channel layer via a high purity density region having higher impurity density than the channel layer.

8. The semiconductor device according to claim 5, wherein the gate electrode and the other main electrode are coupled at a resistance value of 100 Ω or below.

9. The semiconductor device according to claim 1, wherein each field effect transistor includes a nitride semiconductor.

10. The semiconductor device according to claim 1, wherein
the first terminal receives or outputs a DC signal, and
the second terminal receives supply of an operating power supply potential or a reference potential of a high frequency circuit.

11. The semiconductor device according to claim 10, wherein the high frequency circuit includes a power amplifier.

12. The semiconductor device according to claim 1, wherein the multi-gate transistor is included in an electrostatic breakdown protection circuit.

13. A semiconductor module comprising a semiconductor device, wherein
the semiconductor device includes
a multi-gate transistor including a plurality of field effect transistors each having a pair of main electrodes and a gate electrode disposed between the pair of main electrodes, the field effect transistors being electrically coupled in series while sharing the main electrodes,
a first terminal being electrically coupled to one of the main electrodes of the field effect transistor at one end of the series-coupled field effect transistors of the multi-gate transistor, the first terminal receiving or outputting a signal, and
a second terminal being electrically coupled to another of the main electrodes of the field effect transistor at another end of the series-coupled field effect transistors of the multi-gate transistor, the second terminal receiving supply of a fixed potential, wherein
the gate electrode of at least one of the field effect transistors of the multi-gate transistor is electrically coupled to the other main electrode of the same field effect transistor.

14. An electronic apparatus comprising a semiconductor device, wherein
the semiconductor device includes
a multi-gate transistor including a plurality of field effect transistors each having a pair of main electrodes and a gate electrode disposed between the pair of main electrodes, the field effect transistors being electrically coupled in series while sharing the main electrodes,
a first terminal being electrically coupled to one of the main electrodes of the field effect transistor at one end of the series-coupled field effect transistors of the multi-gate transistor, the first terminal receiving or outputting a signal, and
a second terminal being electrically coupled to another of the main electrodes of the field effect transistor at another end of the series-coupled field effect transistors of the multi-gate transistor, the second terminal receiving supply of a fixed potential, wherein
the gate electrode of at least one of the field effect transistors of the multi-gate transistor is electrically coupled to the other main electrode of the same field effect transistor.
